(19) United States
(12) Patent Application Publication
(10) Pub. No.: US 2006/0289877 A1
(43) Pub. Date: Dec. 28, 2006

(54) Semiconductor device

(75) Inventor: Yutaka Hirose, Kyoto (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd, Kadoma-shi (JP)

(21) Appl. No.: 11/474,459

(22) Filed: Jun. 26, 2006

(30) Foreign Application Priority Data
Jun. 27, 2005 (JP) 2005-185828

(51) Int. Cl. H01L 33/00

(52) U.S. Cl. 257/86

(57) ABSTRACT

The barrier φ_{b} between the Fermi level Ef of Se and the valence band of the wide band gap p-type semiconductor becomes the lowest by including the Se layer in the p-type ohmic electrode, and an ohmic contact is achieved that has a resistance far lower than that obtained when the metal layer having high work function of prior art is arranged on the wide band gap p-type semiconductor.

### BACKGROUND OF THE INVENTION

(1) Field of the Invention

The present invention relates to a semiconductor device using a wide band gap semiconductor.

(2) Description of the Related Art

Recently, with increase in demand for a blue light emitting element and an element of high breakdown voltage and high output, research and development are being proceeded on light emitting elements and electronic devices that use SiC, nitride semiconductor and the like (semiconductor in which the band gap is not less than 2 eV is hereinafter referred to as a wide band gap semiconductor) having a wider band gap than that of the conventional semiconductor (hereinafter referred to as a regular semiconductor) such as Si, GaAs and the like.

FIG. 4 is a configuration view showing a conventional wide band gap semiconductor device, and shows a most general configuration when a pn junction is used.

In FIG. 4, an n-type semiconductor layer 12 is formed on a substrate 11, and a p-type semiconductor layer 13 is further formed on the n-type semiconductor layer 12. An n-type ohmic electrode 14 and a p-type ohmic electrode 16 are formed on the n-type semiconductor layer 12 and the p-type semiconductor layer 13, respectively. Contact resistance is one type of performance index of the semiconductor device including the pn junction, where the contact resistance is preferably as low as possible. This is because the loss due to the contact resistance becomes smaller as the contact resistance becomes lower, thereby achieving high efficiency operation.

In the above semiconductor device, a sufficiently low contact resistance of about 10⁻⁶ Ωcm² is achieved by using Ti, Mo, Al and the like for the n-type ohmic electrode 14 with respect to the n-type semiconductor layer 12. However, with respect to the p-type semiconductor layer 13, the contact resistance is extremely high or about 10⁻⁴ Ωcm² even if Pd and the like is used for the p-type ohmic electrode 16, which becomes the main cause of decrease in efficiency of the element.

### SUMMARY OF THE INVENTION

In order to solve the above problem, the semiconductor device of the preset invention aims to reduce the ohmic contact resistance in the wide band gap semiconductor device. In order to achieve the above aim, the semiconductor device of the present invention includes an n-type semiconductor layer formed on a substrate, a p-type semiconductor layer having a band gap of not less than 2 eV stacked on the n-type semiconductor layer with a part of the n-type semiconductor layer being exposed, an n-type ohmic electrode formed on the exposed part of the n-type semiconductor layer, and a p-type ohmic electrode including an Se layer and formed on the p-type semiconductor layer.

The p-type ohmic electrode has a Se layer as its bottom layer that contacts the p-type semiconductor.

The Se layer is not more than 20 nm.

Further, a metal layer of the p-type ohmic electrode that is formed on the Se layer has a film thickness of not less than 100 nm.

Further, an outward emitting prevention film is by exposing the n-type ohmic electrode and the p-type ohmic electrode.

Further, the outward emitting prevention film includes one of Zn and Cu.

Still further, the p-type semiconductor layer and the n-type semiconductor layer are composed of one of SiC and nitride semiconductors.

### BRIEF DESCRIPTION OF THE DRAWINGS

FIG. 1 is a cross sectional view showing a semiconductor device according to the present invention;

FIG. 2A is a diagram showing a difference in interfacial energy caused by a metal stacked on a p-type semiconductor layer according to a prior art;

FIG. 2B is a diagram showing a difference in interfacial energy caused by a metal stacked on a p-type semiconductor layer according to the present invention;

FIG. 3 is a diagram showing a current-voltage characteristic of a pn junction diode produced by a metal stacked on the p-type semiconductor layer, according to the prior art and the present invention; and

FIG. 4 is a configuration view showing a wide band gap semiconductor device according to the prior art.

### DESCRIPTION OF THE PREFERRED EMBODIMENTS

The contact resistance of the ohmic electrode with respect to the p-type wide band gap semiconductor layer is high because of the fact that an energy barrier is produced in injecting a hole to the valence band even when the metal having high work function is used since the band gap of the semiconductor device is wide and the energy level of the valence band of the p-type semiconductor layer is low (deep). Therefore, a conductive layer having a larger work function is preferably used for the ohmic electrode in order to form the ohmic contact in the p-type semiconductor layer of such wide band gap semiconductor device. The present invention thus provides a semiconductor device including an ohmic contact electrode in the p-type semiconductor layer having a band gap of not less than 2 eV, where Se is included in the ohmic electrode. According to such configuration, the work function of Se becomes the highest or 6 eV, and the barrier between the Fermi level of Se and the valence band of the wide band gap p-type semiconductor becomes the lowest, and thus an ohmic contact having the lowest resistance is formed.

Further, the semiconductor device of the present invention is a semiconductor device including an ohmic contact electrode in the p-type semiconductor layer having a band gap of not less than 2 eV, where the bottom layer contacting the p-type semiconductor of the ohmic electrode is Se. According to such configuration, the barrier between the Fermi level of Se having the highest work function (6 eV) and the valence band of the wide band gap p-type semiconductor becomes the lowest, and the ohmic contact having the lowest resistance is formed.

Moreover, the semiconductor device of the present invention is a semiconductor device including an ohmic contact electrode in the p-type semiconductor layer having a band gap of not less than 2 eV, where the bottom layer contacting the p-type semiconductor of the ohmic electrode is Se, the Se layer being not more than 20 nm. The semi-metallic nature of the bulk becomes significant and the conductivity increases if the Se layer is not less than 20 nm. The conductivity of the Se layer is maintained sufficiently high according to the configuration of the present invention.

Further, the semiconductor device of the present invention is a semiconductor device including an ohmic contact electrode in the p-type semiconductor layer having a band gap of not less than 2 eV, where the bottom layer contacting the p-type semiconductor of the ohmic electrode is an Se layer having a film thickness of not more than 20 nm, and a metal layer having a film thickness of not less than 100 nm is formed on the Se layer. According to such configuration, sufficient current is injected to the Se layer, thereby preventing outward diffusion of Se.

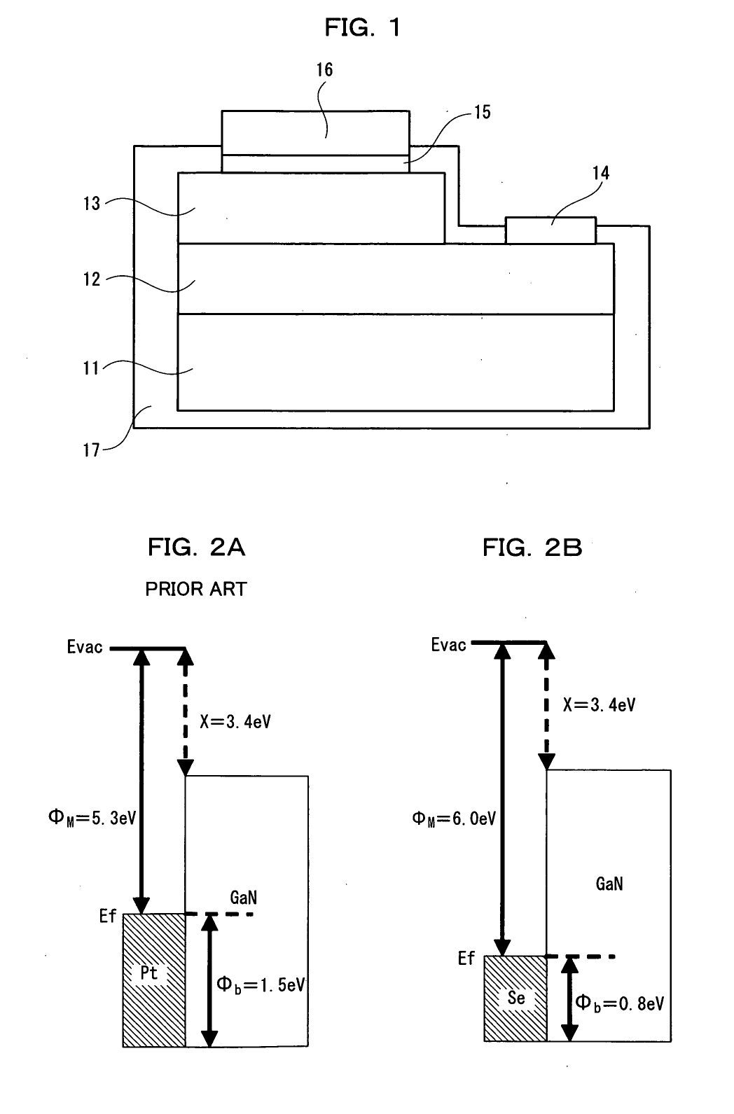

The embodiment of the semiconductor device according to the present invention will now be described with reference to FIGS. 1 to 3.

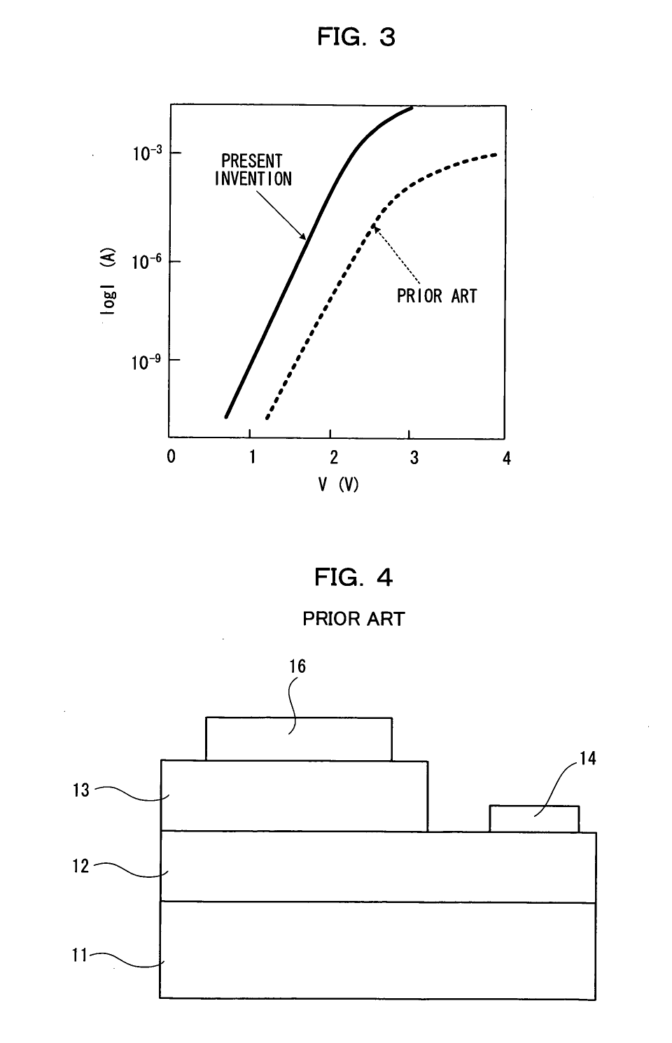

FIG. 1 is a cross sectional view showing a semiconductor device of the present invention, FIG. 2A is a diagram showing the difference in interfacial energy caused by a metal stacked on a conventional p-type semiconductor layer, FIG. 2B is a diagram showing the difference in interfacial energy caused by a metal stacked on a p-type semiconductor layer of the present invention, and FIG. 3 is a diagram showing a current-voltage characteristics of a pn junction diode produced by a metal stacked on the p-type semiconductor layer.

As shown in FIG. 1, a p-type semiconductor layer 13 made of p-type GaN is stacked on an n-type semiconductor layer 12 made of n-type GaN formed on a substrate 11 made of sapphire. After removing a part of the p-type semiconductor layer 13 through etching and exposing the n-type semiconductor layer 12, an n-type ohmic electrode 14, which is an alloy layer including Ti and Al, is formed on the exposed n-type semiconductor layer 12, an Se layer 15 having a thickness of 5 nm is formed on the p-type semiconductor layer 13, and a p-type ohmic electrode layer 16 made of Pd and having a thickness of 200 nm is formed on the Se layer 15. According to such configuration, the work function of Se becomes the highest of 6 eV, and the barrier between the Fermi level of Se and the valence band of the p-type GaN becomes the lowest, and thus an ohmic contact having the lowest resistance is formed. In a region other than the ohmic electrodes, a SiN film 17 and the like can be formed as an outward emitting prevention film of the Se. Further, the SiN film 17 may be doped with a small amount of Zn. Thus, by forming the outward emitting prevention film doped with Zn and the like, even if Se disperses outward from the electrode sections by any chance, Zn reacts with Se and forms a chemically stable ZnSe, which prevents Se from being emitted alone to the outside of the element and causing the contact resistance to increase, and prevents the environment from being polluted by Se as a harmful substance.

An example has been explained in which the Se layer 15 having a thickness of 5 nm is formed at the bottom layer of the p-type ohmic electrode layer 16 on the p-type semiconductor layer 13, but similar effects may be obtained when the thickness is not more than 20 nm, and the Se layer 15 needs not necessarily be formed at the bottom layer of the p-type ohmic electrode layer 16. Moreover, the metal formed on the Se layer 15 is not limited to Pd, and the thickness thereof is desirably not less than 100 nm. Similar effects may also be obtained when the outward emitting prevention film is doped with Cu.

The interfacial energy will now be explained by way of comparison with the prior art, using FIGS. 2A and 2B.

FIG. 2A shows an energy diagram of an interface between a conventional p-type nitride semiconductor (GaN) and an ohmic electrode. Since a metal having high work function is conventionally stacked directly on the p-type GaN surface, an energy barrier φ_{b} of about 1 eV is produced between the valence band and the Fermi level of Pt even if metal Pt having high work function is used.

Whereas, in the ohmic electrode with respect to the wide band gap p-type semiconductor according to the present invention, an energy diagram of the interface between the p-type semiconductor and the electrode as shown in FIG. 2B is obtained by adding the Se layer having a greater work function to the metal layer stacked on the p-type GaN surface. Thus, by adding the Se layer, the work function of Se becomes higher by about 1 eV than that of the metal Pt having the highest work function of 6 eV, and the energy barrier φ_{b} produced between the valence band and the Fermi level of the Se layer is reduced by about 0.7 eV as compared with the prior art. As a result, the ohmic contact resistance with respect to the p-type semiconductor is significantly reduced.

FIG. 3 shows the current-voltage characteristics of the pn junction diode using the electrode including the Se layer of the present invention and the pn junction using a prior art Pd electrode, respectively as ohmic electrode for the p-type semiconductor layer. As apparent from the diagram, according to the present invention, the pn junction is electrically conducted at a voltage lower than that of the prior art, and since the series resistance is low even when high voltage is applied, higher current may be injected.

Therefore, according to the semiconductor device of the present invention, the barrier between the Fermi level of Se and the valence band of the wide band gap p-type semiconductor becomes the lowest by including the Se layer in the p-type ohmic electrode, and the ohmic contact having a significantly lower resistance is achieved as compared with the prior art where the metal layer having high work function is provided on the wide gap p-type semiconductor.

Although the nitride semiconductor is given as an example of the wide band gap semiconductor in the above description, a p-type SiC may also be used instead.

What is claimed is:

1. A semiconductor device comprising:
an n-type semiconductor layer formed on a substrate;
a p-type semiconductor layer having a band gap of not less than 2 eV stacked on the n-type semiconductor layer with a part of the n-type semiconductor layer being exposed;
an n-type ohmic electrode formed on the exposed part of the n-type semiconductor layer; and
a p-type ohmic electrode including an Se layer and formed on the p-type semiconductor layer.

2. The semiconductor device according to claim 1, wherein a bottom layer of the p-type ohmic electrode that contacts the p-type semiconductor is the Se layer.

3. The semiconductor device according to claim 2, wherein the Se layer is not more than 20 nm.

4. The semiconductor device according to claim 1, wherein a metal layer of the p-type ohmic electrode that is formed on the Se layer has a film thickness of not less than 100 nm.

5. The semiconductor device according to claim 2, wherein a metal layer of the p-type ohmic electrode that is formed on the Se layer has a film thickness of not less than 100 nm.

6. The semiconductor device according to claim 3, wherein a metal layer of the p-type ohmic electrode that is formed on the Se layer has a film thickness of not less than 100 nm.

7. The semiconductor device according to claim 1, wherein an outward emission preventing film is formed by exposing the n-type ohmic electrode and the p-type ohmic electrode.

8. The semiconductor device according to claim 2, wherein an outward emission preventing film is formed by exposing the n-type ohmic electrode and the p-type ohmic electrode.

9. The semiconductor device according to claim 7, wherein the outward emitting prevention film includes one of Zn and Cu.

10. The semiconductor device according to claim 8, wherein the outward emitting prevention film includes one of Zn and Cu.

11. The semiconductor device according to claim 1, wherein the p-type semiconductor layer and the n-type semiconductor layer are comprised of one of SiC and nitride semiconductors.

12. The semiconductor device according to claim 2, wherein the p-type semiconductor layer and the n-type semiconductor layer are comprised of one of SiC and nitride semiconductors.

13. The semiconductor device according to claim 3, wherein the p-type semiconductor layer and the n-type semiconductor layer are comprised of one of SiC and nitride semiconductors.

14. The semiconductor device according to claim 4, wherein the p-type semiconductor layer and the n-type semiconductor layer are comprised of one of SiC and nitride semiconductors.

15. The semiconductor device according to claim 5, wherein the p-type semiconductor layer and the n-type semiconductor layer are comprised of one of SiC and nitride semiconductors.

16. The semiconductor device according to claim 6, wherein the p-type semiconductor layer and the n-type semiconductor layer are comprised of one of SiC and nitride semiconductors.

17. The semiconductor device according to claim 7, wherein the p-type semiconductor layer and the n-type semiconductor layer are comprised of one of SiC and nitride semiconductors.

18. The semiconductor device according to claim 8, wherein the p-type semiconductor layer and the n-type semiconductor layer are comprised of one of SiC and nitride semiconductors.

19. The semiconductor device according to claim 9, wherein the p-type semiconductor layer and the n-type semiconductor layer are comprised of one of SiC and nitride semiconductors.

20. The semiconductor device according to claim 10, wherein the p-type semiconductor layer and the n-type semiconductor layer are comprised of one of SiC and nitride semiconductors.
